(19) United States
(12) Patent Application Publication
(10) Pub. No.: US 2026/0104462 A1
(43) Pub. Date: Apr. 16, 2026

(54) ELECTRONIC APPARATUS GENERATING BATTERY STATUS INFORMATION USING ALIVE BLOCK

(71) Applicant: Samsung Electronics Co., Ltd., Suwon-si (KR)

(72) Inventors: Hyukrae PARK, Suwon-si (KR); Sangbin MOON, Suwon-si (KR); Sejong PARK, Suwon-si (KR); Dongjo KIM, Suwon-si (KR); Minhwan SEO, Suwon-si (KR); Jeonghun SEO, Suwon-si (KR)

(73) Assignee: Samsung Electronics Co., Ltd., Suwon-si (KR)

(21) Appl. No.: 19/336,692

(22) Filed: Sep. 23, 2025

(30) Foreign Application Priority Data
Oct. 10, 2024 (KR) 10-2024-0138026
Feb. 19, 2025 (KR) 10-2025-0021537

(51) Int. Cl. G01R 31/367; G01R 31/3842; G01R 31/392

(52) U.S. Cl. CPC G01R 31/367; G01R 31/3842; G01R 31/392

(57) ABSTRACT

Provided is an electronic apparatus including a battery configured to supply power to the electronic apparatus, a battery sensing circuit electrically connected to the battery and configured to generate sensing data corresponding to the battery, and an application processor including an alive block, wherein the alive block includes a memory configured to store the sensing data, and an auxiliary processor configured to generate battery status information based on the sensing data, and the alive block is configured to generate the battery status information in response to the application processor operating in a sleep mode.

### CROSS-REFERENCE TO RELATED APPLICATIONS

This application is based on and claims priority under 35 U.S.C. §119 to Korean Patent Applications Nos. 10-2024-0138026, filed on Oct. 10, 2024, and 10-2025-0021537, filed on Feb. 19, 2025, in the Korean Intellectual Property Office, the disclosures of which are incorporated by reference herein in their entirety.

### BACKGROUND

Various example embodiments of inventive concepts relate to an electronic apparatus, and more particularly, to an electronic apparatus that generates battery status information by using an alive block.

In electronic apparatuses such as mobile devices, battery status information may be calculated via an application processor (AP). However, keeping the AP continuously active in such electronic apparatuses results in unnecessary power consumption, and thus, in specific situations such as when there is low traffic, the AP may switch to a sleep mode, which is a low-power mode, to reduce power consumption. However, when the AP operates in the sleep mode, it may become difficult to continuously calculate a battery status. Therefore, it may be beneficial to provide a method that allows the battery status to be continuously calculated even when the AP is operating in the sleep mode.

### SUMMARY

Various example embodiments of inventive concepts provide an electronic apparatus including an application processor that keeps generating battery status information even when operating in a sleep mode.

Inventive concepts are not limited to the technical features mentioned above, and other technical features not mentioned herein will be clearly understood by those of ordinary skill in the art from the following description.

Some example embodiments of inventive concepts provide an electronic apparatus including a battery configured to supply power to the electronic apparatus, a battery sensing circuit electrically connected to the battery and configured to generate sensing data corresponding to the battery, and an application processor including an alive block, wherein the alive block includes a memory configured to store the sensing data, and an auxiliary processor configured to generate battery status information based on the sensing data, and the alive block is configured to generate the battery status information in response to the application processor operating in a sleep mode.

Some example embodiments of inventive concepts provide an electronic apparatus including a battery configured to supply power to the electronic apparatus, a battery sensing circuit electrically connected to the battery and configured to generate sensing data corresponding to the battery, and an application processor including an alive block and a main processor, wherein the alive block includes a memory configured to store the sensing data, and an auxiliary processor configured to write the sensing data to the memory, and the main processor is configured to read the sensing data from the memory and generate battery status information based on the sensing data.

Some example embodiments of inventive concepts provide an electronic apparatus including a battery configured to supply power to the electronic apparatus, a battery sensing circuit electrically connected to the battery and configured to generate sensing data corresponding to the battery, and an application processor including an alive block and a main processor, wherein the alive block includes a memory configured to store a sensing data group including the sensing data, and an auxiliary processor configured to write the sensing data to the memory in response to the application processor operating in a sleep mode, and the main processor is configured to read the sensing data group from the memory and generate accumulated battery status information based on the sensing data group, in response to an operation mode of the application processor being changed from the sleep mode to an active mode.

### BRIEF DESCRIPTION OF THE DRAWINGS

Various example embodiments will be more clearly understood from the following detailed description taken in conjunction with the accompanying drawings in which:

FIG. 1 is a diagram for explaining an electronic apparatus, according to some example embodiments;

FIG. 2 is a diagram for explaining an electronic apparatus, according to some example embodiments;

FIG. 3 is a diagram for explaining sensing data, according to some example embodiments;

FIG. 4 is a diagram for explaining a battery sensing circuit and a battery, according to some example embodiments;

FIG. 5 is a diagram for explaining an internal circuit of a battery, according to some example embodiments;

FIG. 6 is a diagram for explaining an electronic apparatus, according to some example embodiments;

FIG. 7 is a flowchart for explaining an operating method of an electronic apparatus, according to some example embodiments;

FIG. 8 is a diagram for explaining an electronic apparatus, according to some example embodiments;

FIG. 9 is a diagram for explaining sensing data, according to some example embodiments;

FIG. 10 is a diagram for explaining an electronic apparatus, according to some example embodiments;

FIG. 11 is a flowchart for explaining an operating method of an electronic apparatus, according to some example embodiments;

FIG. 12 is a diagram for explaining an electronic apparatus, according to some example embodiments;

FIGS. 13A and 13B are diagrams for explaining an electronic apparatus, according to some example embodiments;

FIG. 14 is a flowchart for explaining an operating method of an electronic apparatus, according to some example embodiments; and

FIG. 15 is a block diagram illustrating a computer system, according to some example embodiments.

### DETAILED DESCRIPTION

Hereinafter, some example embodiments will be described in detail with reference to the accompanying drawings. When descriptions are given with reference to drawings, identical or corresponding components may be given with identical drawing reference numbers, and duplicate descriptions thereof are omitted.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to the other elements and/or properties thereof. Elements and/or properties thereof that are “the same” or “equal” to other elements and/or properties thereof will be understood to include elements and/or properties thereof that are identical to, the same as, or equal to the other elements and/or properties thereof within manufacturing tolerances and/or material tolerances (e.g., ±10%). Elements and/or properties thereof that are identical, the same, and/or equal as other elements and/or properties thereof may be structurally the same or substantially the same, functionally the same or substantially the same, and/or compositionally the same or substantially the thereof.

As used herein, the term “when” may be interpreted to mean “in response to.” For example, if it is described that A is configured to perform X when B occurs, this may be interpreted to mean that A is configured to perform X in response to the occurrence of B.

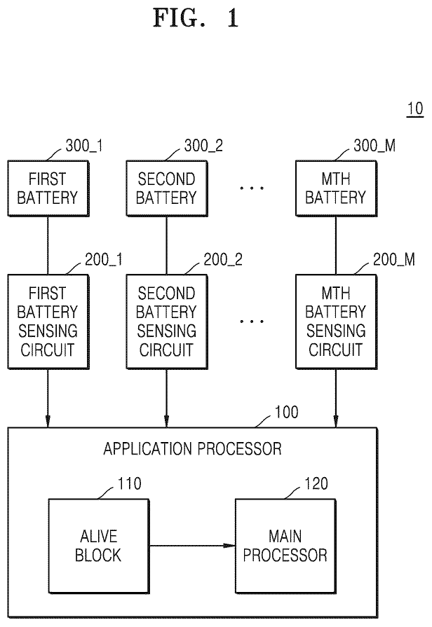

FIG. 1 is a diagram for explaining an electronic apparatus 10, according to some example embodiments.

Referring to FIG. 1, the electronic apparatus 10 may include an application processor 100, first to M^{th} battery sensing circuits 200_1 to 200_M (wherein M is a natural number of 2 or more), and first to M^{th} batteries 300_1 to 300_M.

In some example embodiments, the electronic apparatus 10 may be implemented as various computing apparatuses or mobile apparatuses, such as a mobile phone, a smartphone, a tablet personal computer (PC), a personal digital assistant (PDA), an enterprise digital assistant (EDA), a portable multimedia player (PMP), a digital camera, a music player, a portable game console, a navigation device, a wearable device, an Internet of things (IoT) device, an Internet of everything (IoE) device, an e-book, a virtual reality (VR) device, and an augmented reality (AR) device, but example embodiments are not limited thereto.

The application processor 100 may be implemented in the form of a system-on-chip (SoC). The application processor 100 may include at least one of a central processing unit (CPU), a graphics processing unit (GPU), a digital signal processor (DSP), an image signal processor (ISP), a neural processing unit (NPU), and a micro controller unit (MCU), but example embodiments are not limited thereto. In some example embodiments, a processing unit included in the application processor 100 may be referred to as a processor.

The application processor 100 may execute an operating system (OS) and a variety of application software. Alternatively or additionally, the application processor 100 may include, or be connected to, a memory interface, a peripheral interface (for example, a universal serial bus (USB), a display, a camera, a sensor, etc.), a power management circuit, or a security module, thereby collectively controlling and managing the electronic apparatus 10.

In some example embodiments, the application processor 100 may operate in at least two operation modes, e.g., an active mode or a sleep mode, but example embodiments are not limited thereto.

The active mode may refer to a state in which a main processor (CPU, GPU, DSP, NPU, etc.) and a peripheral circuit, in the application processor 100, are supplied (or normally supplied) with power and are provided with a clock signal, thereby enabling an OS and an application to operate. In some example embodiments, when operating in the active mode, the application processor 100 is capable of performing high-performance computations and may perform main functions of a device in real time, such as user interface (UI) processing, network communication, and sensor data processing. While the application processor 100 is operating in the active mode, most of hardware constituting the application processor 100 may operate in order to provide (or smoothly provide) a user experience (UX) and a multimedia function to a user. In some example embodiments, power consumed by the application processor 100 while operating in the active mode may be higher (or relatively higher) than when the application processor 100 operates in the sleep mode. Herein, the active mode may be referred to as a first mode or a normal mode.

The sleep mode may refer to a state in which some or most circuits of the application processor 100 are deactivated or clock signal supply is blocked. In some example embodiments, when the application processor 100 operates in the sleep mode, a clock signal applied to a main computation block including a processor may be stopped or power supply thereto may be cut off, thereby minimizing (or reducing) standby power. However, functions essential (or used) for maintaining system operation, such as battery status detection, alarms, real-time clock (RTC) signaling, sensor interrupts, and wireless communication packet reception, may be monitored and controlled via an alive block 110. In some example embodiments, when a user input (a power button, a touch event, etc.) or an external event (a timer, a wireless signal, etc.) are detected in the sleep mode, the application processor 100 may change its operation mode from the sleep mode to the active mode by re-applying power and a clock signal. Herein, the sleep mode may be referred to as a second mode or a low-power mode.

The application processor 100 may include the alive block 110 and a main processor 120.

The alive block 110 may refer to a hardware area, circuit, or sub-system designed to maintain (or always maintain) certain functions (or core functions), such as power management, security, and system event handling, in the application processor 100. For example, even when the application processor 100 operates in the sleep mode, the alive block 110 may continue to operate to perform, for example, a power management function. In some example embodiments, the alive block 110 may be referred to as an always-on block or an always-on domain.

In some example embodiments, even when the application processor 100 operates in the sleep mode, the alive block 110 may receive sensing data from the first to M^{th} battery sensing circuits 200_1 to 200_M.

In some example embodiments, the alive block 110 may include an auxiliary processor, and the auxiliary processor may have lower power consumption than the main processor 120.

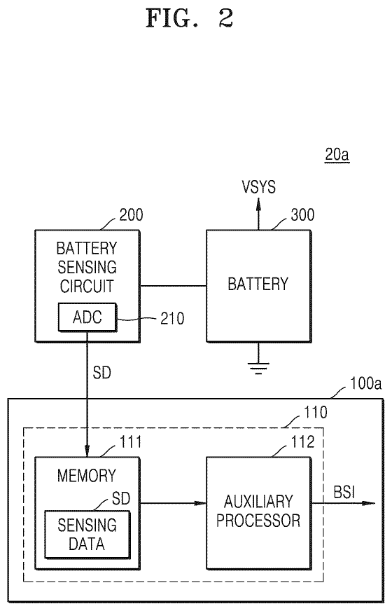

Each battery sensing circuit of the first to M^{th} battery sensing circuits 200_1 to 200_M may be electrically connected to respective a battery among the first to M^{th} batteries 300_1 to 300_M. The first to M^{th} batteries 300_1 to 300_M may provide operating power to operate (or provide power required or used to operate) the electronic apparatus 10. FIG. 1 illustrates that the electronic apparatus 10 includes a plurality of battery sensing circuits and a plurality of batteries, but example embodiments are not limited thereto. For example, the electronic apparatus 10 may include only one battery sensing circuit and only one battery. This will be described with reference to FIG. 2.

In some example embodiments, a battery sensing circuit may be referred to as a fuel gauge chip, a power management integrated circuit (PMIC), or an interface PMIC (IF PMIC).

The first to M^{th} battery sensing circuits 200_1 to 200_M may sense the first to M^{th} batteries 300_1 to 300_M. For example, the first to M^{th} battery sensing circuits 200_1 to 200_M may generate sensing data based on values (for example, voltages) sensed from the first to M^{th} batteries 300_1 to 300_M, and the generated sensing data may be provided to the application processor 100.

The application processor 100 may generate battery status information by calculating a battery status based on the received sensing data. In some example embodiments, the application processor 100 may use a fuel gauge (FG) algorithm to calculate the battery status.

The FG algorithm may refer to an algorithm used to calculate, in real time, state of charge information representing the amount of energy remaining in a battery, state of battery health information representing the degree of deterioration of a battery, internal short-circuit information representing whether there is a short circuit inside a battery, etc. The FG algorithm may be implemented based on at least one model among an equivalent circuit model (ECM) or an electro-chemical thermal (ECT) model. The ECM may refer to a model that uses an equivalent circuit including basic circuit elements such as a resistor, a capacitor, and a voltage source to simulate electrical characteristics of a battery. The ECT model may refer to a model that considers electrochemical reactions inside a battery and thermal characteristics (e.g., heat generation, heat distribution, etc.) simultaneously.

For energy management (or efficient energy management) of the electronic apparatus 10, it may be beneficial (or it may be essential) to continuously monitor the battery status. However, when the application processor 100 operates in the sleep mode, the operation of the main processor 120 is deactivated, and thus, it may be difficult to monitor the battery status, and accordingly, continuous generation of the battery status information may be disrupted. By using the alive block 110, an electronic apparatus according to some example embodiments may keep generating the battery status information even when the application processor 100 operates in the sleep mode.

FIG. 2 is a diagram for explaining an electronic apparatus 20a, according to some example embodiments. FIG. 2 may be explained with reference to FIG. 1, and redundant descriptions may be omitted.

Referring to FIG. 2, the electronic apparatus 20a of FIG. 2 may correspond to the electronic apparatus 10 of FIG. 1. The electronic apparatus 20a may include an application processor 100a, a battery sensing circuit 200, and a battery 300. The battery 300 may provide power to operate (or provide power required or used to operate) the electronic apparatus 20a, via an operating voltage VSYS.

The application processor 100a may include the alive block 110. The alive block 110 may include a memory 111 and an auxiliary processor 112.

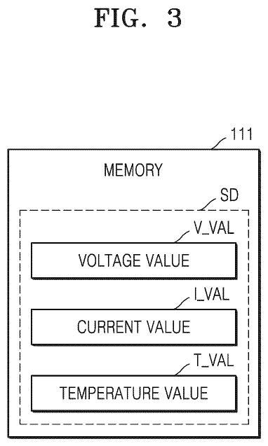

The memory 111 may store sensing data SD. The sensing data SD may be data provided from the battery sensing circuit 200. A structure of the sensing data SD stored in the electronic apparatus 20a of FIG. 2 will be described with reference to FIG. 3.

The memory 111 may be hardware that may store information and may be accessed by the auxiliary processor 112. For example, the memory 111 may include read-only memory (ROM), random-access memory (RAM), dynamic RAM (DRAM), double-data-rate DRAM (DDR DRAM), synchronous DRAM (SDRAM), static RAM (SRAM), magnetoresistive RAM (MRAM), programmable ROM (PROM), erasable PROM (EPROM), electrically EPROM, flash memory, polymer memory, phase-change memory, ferroelectric memory, silicon-oxide-nitride-oxide-silicon (SONOS) memory, a magnetic card/disk, an optical card/disk, or a combination of at least two thereof, but example embodiments are not limited thereto.

The auxiliary processor 112 may read the sensing data SD stored in the memory 111. The auxiliary processor 112 may generate battery status information BSI, by performing a calculation using the FG algorithm based on the read sensing data SD. The battery status information BSI may be information representing a status of the battery 300 at a time point at which the battery sensing circuit 200 senses the battery 300.

The battery status information BSI may include a variety of information representing a status of a battery. In some example embodiments, the battery status information BSI may include at least one of state of charge information representing the amount of energy remaining in the battery, state of battery health information representing the degree of deterioration of the battery, or an internal short-circuit information representing whether there is a short circuit inside the battery.

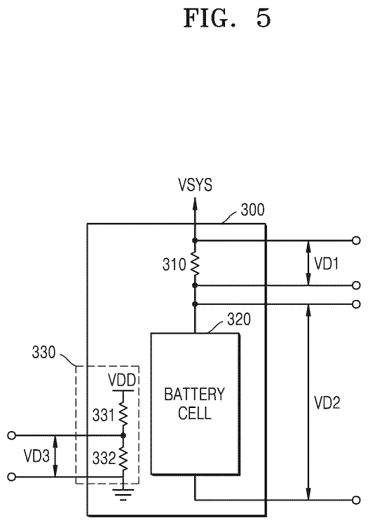

The battery sensing circuit 200 may include an analog-to-digital converter (ADC). The battery sensing circuit 200 may be electrically connected to the battery 300. The battery sensing circuit 200 may monitor the status of the battery 300 by sensing the battery 300 periodically, for example, every second, but example embodiments are not limited thereto. In some example embodiments, a period during which the battery sensing circuit 200 senses the battery 300 may be referred to as a reference period. The battery sensing circuit 200 may sense an analog signal (for example, a voltage) from the battery 300, and may obtain a voltage value, current value, and temperature value of the battery 300 by converting the analog signal into the sensing data SD, which is a digital value. A detailed description of how the battery sensing circuit 200 obtains the voltage value, current value, and temperature value of the battery 300 will be described with reference to FIG. 5.

The application processor 100a may receive the sensing data SD from the battery sensing circuit 200 periodically, for example, every second, but example embodiments are not limited thereto. In some example embodiments, a period during which the sensing data SD is received may be referred to as a reference period. In some example embodiments, the battery sensing circuit 200 may provide the sensing data SD to the memory 111 in the alive block 110. Therefore, even when the application processor 100a operates in the sleep mode, the alive block 110 may read the sensing data SD stored in the memory 111 via the auxiliary processor 112 and may generate the battery status information BSI.

In some example embodiments, the application processor 100a may communicate with the battery sensing circuit 200 via an inter-integrated circuit (I2C) protocol.

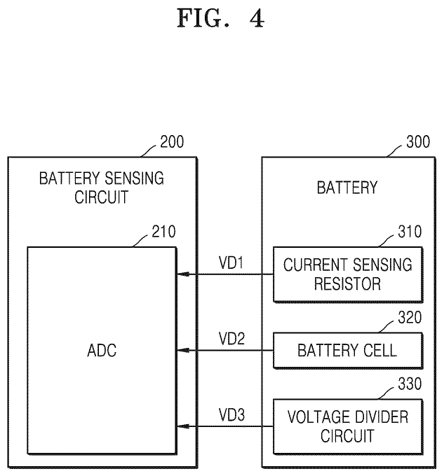

FIG. 3 is a diagram for explaining the sensing data SD, according to some example embodiments. FIG. 4 is a diagram for explaining the battery sensing circuit 200 and the battery 300, according to some example embodiments. FIG. 5 is a diagram for explaining an internal circuit of the battery 300, according to some example embodiments. FIGS. 3, 4, and 5 may be described with reference to FIGS. 1 and 2, and redundant descriptions may be omitted.

Referring to FIG. 3, the sensing data SD may include a voltage value V_VAL, a current value I_VAL, and a temperature value T_VAL. Each of the voltage value V_VAL, the current value I_VAL, and the temperature value T_VAL may be a digital value including k bits (wherein k is a natural number of 2 or more). For example, the voltage value V_VAL, the current value I_VAL, and the temperature value T_VAL may each be a 16-bit value, but example embodiments are not limited thereto. For example, the voltage value V_VAL, the current value I_VAL, and the temperature value T_VAL may each have bit value that is more or less than a 16-bit value.

The battery sensing circuit 200 may convert the analog signal (for example, a voltage) measured from the battery 300 into a digital value. The digital value is the sensing data SD and may be provided to the alive block 110.

Referring to FIGS. 4 and 5, the battery 300 may include a current sensing resistor 310, a battery cell 320, and a voltage divider circuit 330.

Herein, when the battery sensing circuit 200 senses the battery 300, it may mean that the battery sensing circuit 200 measures voltages at both terminals of each of the current sensing resistor 310, the battery cell 320, and a thermistor 332, which are included in the battery 300.

The operating voltage VSYS used to operate (or required to operate) the application processor 100a may be output via a first terminal of the current sensing resistor 310. The first terminal of the current sensing resistor 310 may be electrically connected to the application processor 100a. A second terminal of the current sensing resistor 310 may be electrically connected to the battery cell 320. Each of the first terminal and the second terminal of the current sensing resistor 310 may be electrically connected to an ADC 210. A voltage difference between the first terminal and the second terminal of the current sensing resistor 310 may be referred to as a first dual-terminal voltage VD1. The ADC 210 may convert the first dual-terminal voltage VD1 into a digital value. The battery sensing circuit 200 may generate the current value I_VAL based on the digital value corresponding to the first dual-terminal voltage VD1. The current value I_VAL may be a value corresponding to a current of the battery 300 (for example, an output current of the battery 300).

A first terminal of the battery cell 320 may be electrically connected to the current sensing resistor 310. A second terminal of the battery cell 320 may be electrically connected to the ADC 210. Each of the first terminal and the second terminal of the battery cell 320 may be electrically connected to the ADC 210. A voltage difference between the first terminal and the second terminal of the battery cell 320 may be referred to as a second dual-terminal voltage VD2. The ADC 210 may convert the second dual-terminal voltage VD2 into a digital value. The battery sensing circuit 200 may generate the voltage value V_VAL based on the digital value corresponding to the second dual-terminal voltage VD2. The voltage value V_VAL may be a value corresponding to a voltage of the battery 300 (for example, an output voltage of the battery 300).

The voltage divider circuit 330 may include a reference resistor 331 and the thermistor 332. The thermistor 332 may be an element whose resistance value varies according to a temperature of the battery 300. In some example embodiments, the thermistor 332 may be a negative temperature coefficient (NTC) thermistor. The NTC thermistor may have a characteristic whereby a resistance value decreases when temperature increases. Herein, the description is provided under an assumption that the thermistor 332 is an NTC thermistor, but example embodiments are not limited thereto. For example, the thermistor 332 may be a positive temperature coefficient (PTC) thermistor.

A power voltage VDD may be applied to a first terminal of the reference resistor 331. A second terminal of the reference resistor 331 may be electrically connected to a first terminal of the thermistor 332. The first terminal and a second terminal of the thermistor 332 may be electrically connected to the ADC 210. The first terminal of the thermistor 332 may be electrically connected to the second terminal of the reference resistor 331. The second terminal of the thermistor 332 may be electrically connected to a ground node. In some example embodiments, the power voltage VDD may be a voltage generated by a PMIC provided in the electronic apparatus 20a. The power voltage VDD may be different from the operating voltage VSYS.

A voltage difference between the first terminal and the second terminal of the thermistor 332 may be referred to as a third dual-terminal voltage VD3. The ADC 210 may convert the third dual-terminal voltage VD3 into a digital value. The battery sensing circuit 200 may generate the temperature value T_VAL based on the digital value corresponding to the third dual-terminal voltage VD3. The temperature value T_VAL may be a value corresponding to a temperature of the battery 300.

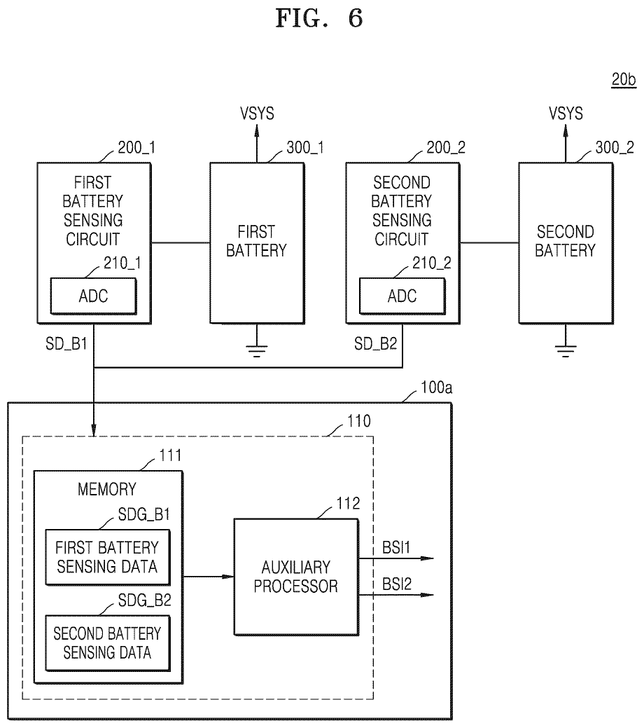

FIG. 6 is a diagram for explaining an electronic apparatus 20b, according to some example embodiments. FIG. 6 may be explained with reference to FIGS. 1 and 2, and redundant descriptions may be omitted.

Referring to FIG. 6, the electronic apparatus 20b of FIG. 6 may correspond to the electronic apparatus 10 of FIG. 1. The electronic apparatus 20b of FIG. 6 may be configured similarly to the electronic apparatus 20a of FIG. 2, but unlike the electronic apparatus 20a of FIG. 2, the electronic apparatus 20b of FIG. 6 may include a plurality of batteries. FIG. 6 illustrates that the electronic apparatus 20b includes two batteries, e.g., the first battery 300_1 and the second battery 300_2, but example embodiments are not limited thereto.

The electronic apparatus 20b may include the application processor 100a, the first battery sensing circuit 200_1, the second battery sensing circuit 200_2, the first battery 300_1, and the second battery 300_2.

Each of the first battery 300_1 and the second battery 300_2 may provide power to operate (or may provide power used or required to operate) the electronic apparatus 20b, via the operating voltage VSYS.

The first battery sensing circuit 200_1 may be electrically connected to the first battery 300_1. The first battery sensing circuit 200_1 may include a first ADC 210_1. The first battery sensing circuit 200_1 may provide first battery sensing data SD_B1 corresponding to the first battery 300_1 to the memory 111, by periodically sensing the first battery 300_1 via the first ADC 210_1.

The second battery sensing circuit 200_2 may be electrically connected to the second battery 300_2. The second battery sensing circuit 200_2 may include a second ADC 210_2. The second battery sensing circuit 200_2 may provide second battery sensing data SD_B2 corresponding to the second battery 300_2 to the memory 111, by periodically sensing the second battery 300_2 via the second ADC 210_2.

In some example embodiments, each of the first battery sensing data SD_B1 and the second battery sensing data SD_B2 may have the same structure as the sensing data SD shown in FIG. 3.

In some example embodiments, the first battery sensing data SD_B1 and the second battery sensing data SD_B2 may be provided to the application processor 100a via a same input/output pin provided in the application processor 100a. Communication between the application processor 100a and each of the first battery sensing circuit 200_1 and the second battery sensing circuit 200_2 may follow the I2C protocol.

The auxiliary processor 112 may read the first battery sensing data SD_B1 and the second battery sensing data SD_B2, which are stored in the memory 111. The auxiliary processor 112 may generate first battery status information BSI1 representing a status of the first battery 300_1, by performing a calculation using the FG algorithm based on the read first battery sensing data SD_B1. Alternatively or additionally, the auxiliary processor 112 may generate second battery status information BSI2 representing a status of the second battery 300_2, by performing a calculation using the FG algorithm based on the read second battery sensing data SD_B2.

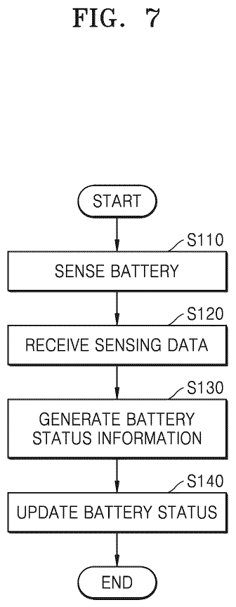

FIG. 7 is a flowchart for explaining an operating method of an electronic apparatus, according to some example embodiments. FIG. 7 may be a flowchart for explaining an operating method of the electronic apparatus 20a of FIG. 2 and the electronic apparatus 20b of FIG. 6. Hereinafter, the operation of the electronic apparatus 20a of FIG. 2 is mainly described, but it may be understood that the electronic apparatus 20b of FIG. 6 may operate in the same (or in a similar) manner. FIG. 7 may be explained with reference to FIGS. 1, 2, and 6, and redundant descriptions may be omitted.

Referring to FIG. 7, in operation S110, the electronic apparatus 20a may sense the battery 300 via the battery sensing circuit 200. The electronic apparatus 20a may generate the sensing data SD based on a sensing result.

In some example embodiments, the battery sensing circuit 200 may sense the first dual-terminal voltage VD1 which is a voltage sensed (or voltages sensed) at both terminals of the current sensing resistor 310 of the battery 300, and may generate the current value I_VAL based on the first dual-terminal voltage VD1.

In some example embodiments, the battery sensing circuit 200 may sense the second dual-terminal voltage VD2 which is a voltage sensed (or voltages sensed) at both terminals of the battery cell 320 of the battery 300, and may generate the voltage value V_VAL based on the second dual-terminal voltage VD2.

In some example embodiments, the battery sensing circuit 200 may sense the third dual-terminal voltage VD3 which is a voltage sensed (or voltages sensed) at both terminals of the thermistor 332 of the battery 300, and may generate the temperature value T_VAL based on the third dual-terminal voltage VD3.

In operation S120, the electronic apparatus 20a may receive the sensing data SD from the battery sensing circuit 200 via the alive block 110. The electronic apparatus 20a may store the sensing data SD in the memory 111.

In operation S130, the electronic apparatus 20a may read, via the auxiliary processor 112, the sensing data SD stored in the memory 111, by accessing the memory 111. The electronic apparatus 20a may generate the battery status information BSI based on the sensing data SD read via the auxiliary processor 112.

In some example embodiments, when the auxiliary processor 112 generates the battery status information BSI, it may mean that the auxiliary processor 112 generates the battery status information BSI by performing a calculation based on the sensing data SD and the FG algorithm.

In operation S140, the electronic apparatus 20a may update a battery status (for example, the remaining capacity of battery and the degree of battery deterioration) of the electronic apparatus 20a based on the battery status information BSI.

In some example embodiments, the electronic apparatus 20a may further include a display apparatus such as a display. The battery status may be displayed on the display apparatus, such as a display, included in the electronic apparatus 20a so as to be visually identifiable by a user.

In some example embodiments, the electronic apparatus 20a may perform operation S110 to operation S140 periodically (for example, at each reference period).

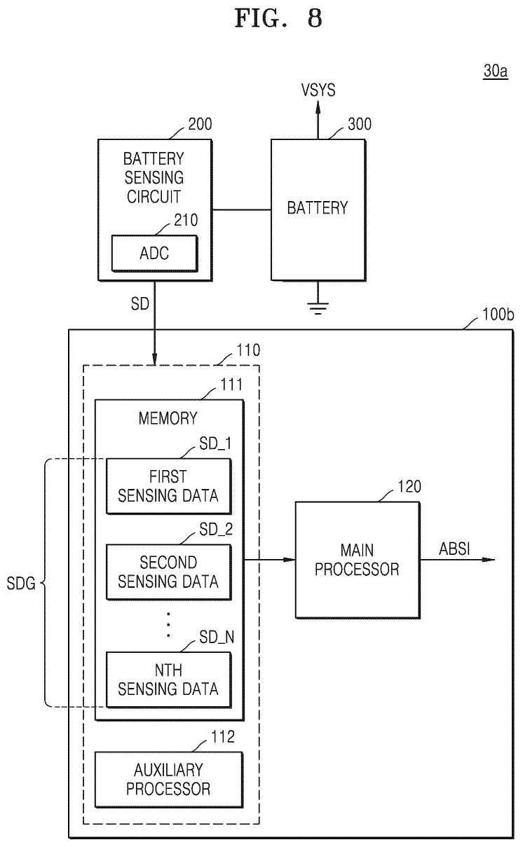

FIG. 8 is a diagram for explaining an electronic apparatus 30a, according to some example embodiments. FIG. 8 may be explained with reference to FIG. 1, and redundant descriptions may be omitted.

Referring to FIG. 8, the electronic apparatus 30a of FIG. 8 may correspond to the electronic apparatus 10 of FIG. 1. The electronic apparatus 30a may include an application processor 100b, the battery sensing circuit 200, and the battery 300. The battery 300 may provide power to operate (or the power used or required to operate) the electronic apparatus 30a, via the operating voltage VSYS.

The application processor 100b may include the alive block 110 and the main processor 120. The alive block 110 may include the memory 111 and the auxiliary processor 112.

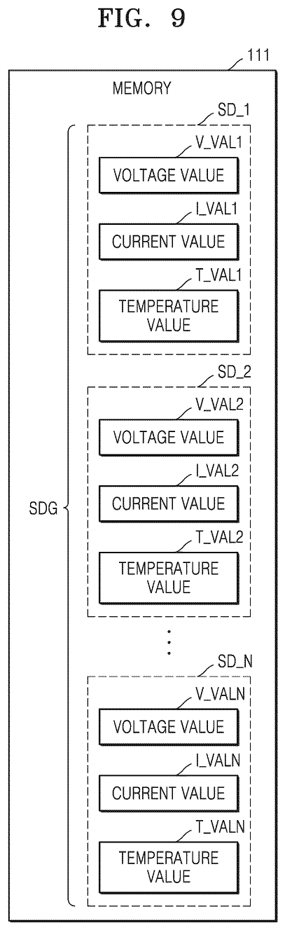

The memory 111 may store a sensing data group SDG. The sensing data group SDG may include first to N^{th} sensing data SD_1 to SD_N (wherein n is a natural number of 2 or more). The first to N^{th} sensing data SD_1 to SD_N may be data provided from the battery sensing circuit 200. Structures of the first to N^{th} sensing data SD_1 to SD_N stored in the electronic apparatus 30a of FIG. 8 will be described with reference to FIG. 9.

The electronic apparatus 30a may provide the sensing data SD to the alive block 110 regardless of the operation mode of the application processor 100b, and the alive block 110 may store the received sensing data SD in the memory 111.

In some example embodiments, when the operation mode of the application processor 100b is the active mode, the battery sensing circuit 200 may provide the sensing data SD to the alive block 110.

In some example embodiments, when the operation mode of the application processor 100b is the sleep mode, the battery sensing circuit 200 may provide the sensing data SD to the alive block 110.

As the auxiliary processor 112 writes, to the memory 111, the sensing data SD received from the battery sensing circuit 200, the sensing data SD may be stored in the memory 111.

In some example embodiments, the battery sensing circuit 200 may sense the battery 300 at each reference period (for example, every second), and the alive block 110 may receive the sensing data SD from the battery sensing circuit 200 at each reference period and may store the received sensing data SD. For example, the sensing data SD generated by the battery sensing circuit 200 sensing the battery 300 at a first time point may be stored in the memory 111, as the first sensing data SD_1. Alternatively or additionally, for example, the sensing data SD generated by the battery sensing circuit 200 sensing the battery 300 at a second time point may be stored in the memory 111, as the second sensing data SD_2. Alternatively or additionally, for example, the sensing data SD generated by the battery sensing circuit 200 sensing the battery 300 at an N^{th} time point may be stored in the memory 111, as the N^{th} sensing data SD_N.

The main processor 120 may read the sensing data group SDG stored in the memory 111, when the application processor 100b operates in the active mode.

In some example embodiments, the main processor 120 may read the sensing data group SDG from the memory 111 and initialize the memory 111 by erasing the sensing data group SDG stored in the memory 111.

In some example embodiments, the auxiliary processor 112 may not be deactivated (e.g., may be in an active state) even when the application processor 100b operates in the sleep mode. The main processor 120 may be deactivated when the application processor 100b operates in the sleep mode.

The main processor 120 may generate accumulated battery status information ABSI, by performing a calculation based on the sensing data group SDG and the FG algorithm. The accumulated battery status information ABSI may be information that cumulatively includes battery status information at each time point, from the first time point to the N^{th} time point.

In some example embodiments, the accumulated battery status information ABSI generated by the main processor 120 of the electronic apparatus 30a may be simply referred to as battery status information.

In some example embodiments, the application processor 100b may communicate with the battery sensing circuit 200 via the I2C protocol.

In some example embodiments, when the application processor 100b is in the sleep mode, the electronic apparatus 30a may store a result of sensing the battery 300 via the alive block 110, and when the application processor 100b is in the active mode, the electronic apparatus 30a may generate the accumulated battery status information ABSI, based on the sensing data group SDG which is stored in the alive block 110 while the application processor 100b is operating in the sleep mode. Accordingly, the electronic apparatus 30a may keep indicating the status of the battery 300.

FIG. 9 is a diagram for explaining the sensing data SD, according to some example embodiments. FIG. 9 may be explained with reference to FIGS. 1, 3, and 8, and redundant descriptions may be omitted.

Referring to FIG. 9, each of the first to N^{th} sensing data SD_1 to SD_N may have the same structure as the sensing data SD of FIG. 3.

In some example embodiments, the first sensing data SD_1 may include values obtained by sensing the battery 300 at the first time point. For example, the first sensing data SD_1 may include a first voltage value V_VAL1 representing a voltage of the battery 300 at the first time point, a first current value I_VAL1 representing a current of the battery 300 at the first time point, and a first temperature value T_VAL1 representing a temperature of the battery 300 at the first time point. Likewise, the second sensing data SD_2 may include a value obtained by sensing the battery 300 at the second time point, and the N^{th} sensing data SD_N may include a value obtained by sensing the battery 300 at the N^{th} time point.

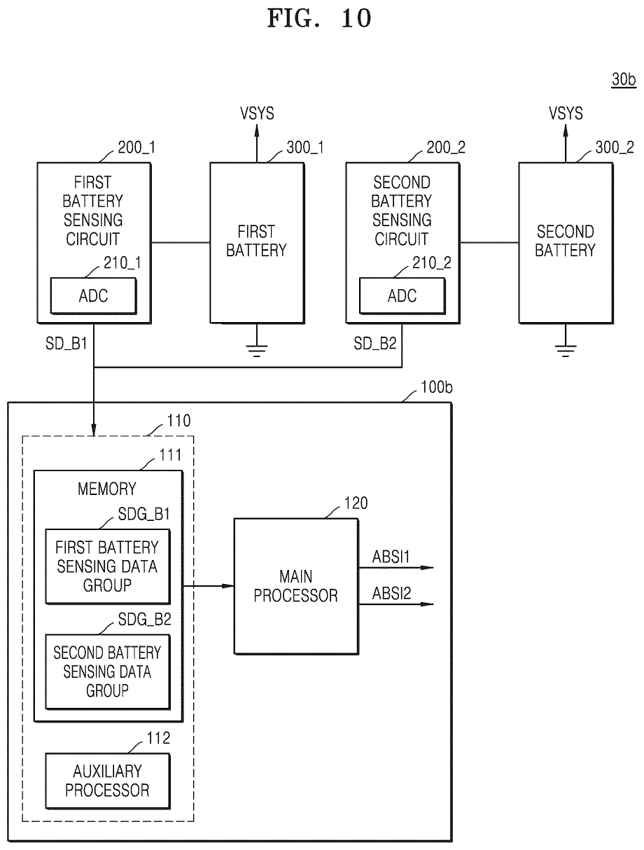

FIG. 10 is a diagram for explaining an electronic apparatus 30b, according to some example embodiments. FIG. 10 may be explained with reference to FIGS. 1, 8, and 9, and redundant descriptions may be omitted.

Referring to FIG. 10, the electronic apparatus 30b of FIG. 10 may correspond to the electronic apparatus 10 of FIG. 1. The electronic apparatus 30b of FIG. 10 may be configured similarly to the electronic apparatus 30a of FIG. 8, but unlike the electronic apparatus 30a of FIG. 8, the electronic apparatus 30b of FIG. 10 may include a plurality of batteries. FIG. 8 illustrates that the electronic apparatus 30b includes two batteries, e.g., the first battery 300_1 and the second battery 300_2, but example embodiments are not limited thereto.

The electronic apparatus 30b may include the application processor 100b, the first battery sensing circuit 200_1, the second battery sensing circuit 200_2, the first battery 300_1, and the second battery 300_2.

Each of the first battery 300_1 and the second battery 300_2 may provide power to operate (or provide power used or required to operate) the electronic apparatus 30b, via the operating voltage VSYS.

The first battery sensing circuit 200_1 may be electrically connected to the first battery 300_1. The first battery sensing circuit 200_1 may include the first ADC 210_1. The first battery sensing circuit 200_1 may provide first battery sensing data SD_B1 corresponding to the first battery 300_1 to the alive block 110, by periodically sensing the first battery 300_1 via the first ADC 210_1.

The second battery sensing circuit 200_2 may be electrically connected to the second battery 300_2. The second battery sensing circuit 200_2 may include the second ADC 210_2. The second battery sensing circuit 200_2 may provide second battery sensing data SD_B2 corresponding to the second battery 300_2 to the alive block 110, by periodically sensing the second battery 300_2 via the second ADC 210_2.

In some example embodiments, each of the first battery sensing data SD_B1 and the second battery sensing data SD_B2 may have the same structure as the sensing data SD shown in FIG. 3.

In some example embodiments, the first battery sensing data SD_B1 and the second battery sensing data SD_B2 may be provided to the application processor 100b via a same input/output pin provided in the application processor 100b. Communication between the application processor 100b and each of the first battery sensing circuit 200_1 and the second battery sensing circuit 200_2 may follow the I2C protocol.

Regardless of whether the operation mode of the application processor 100b is the active mode or the sleep mode, the alive block 110 may store, in the memory 111, the first battery sensing data SD_B1 and the second battery sensing data SD_B2, which are respectively received from the first battery sensing circuit 200_1 and the second battery sensing circuit 200_2.

In some example embodiments, when the operation mode of the application processor 100b is the active mode, the main processor 120 may read, from the memory 111, a first battery sensing data group SDG_B1 and a second battery sensing data group SDG_B2, which are stored in the memory 111. Each of the first battery sensing data group SDG_B1 and the second battery sensing data group SDG_B2 may correspond to a sensing data group SD_G shown in FIG. 9. Herein, the first battery sensing data group SDG_B1 may refer to a set of first battery sensing data SD_B1 measured according to the reference period. The second battery sensing data group SDG_B2 may refer to a set of second battery sensing data SD_B2 measured according to the reference period.

The main processor 120 may generate first accumulated battery status information ABSI1 representing the status of the first battery 300_1 from the first time point to the N^{th} time point, by performing a calculation using the FG algorithm based on the read first battery sensing data group SDG_B1. The main processor 120 may generate second accumulated battery status information ABSI2 representing the status of the second battery 300_2 from the first time point to the N^{th} time point, by performing a calculation using the FG algorithm based on the read second battery sensing data group SDG_B2.

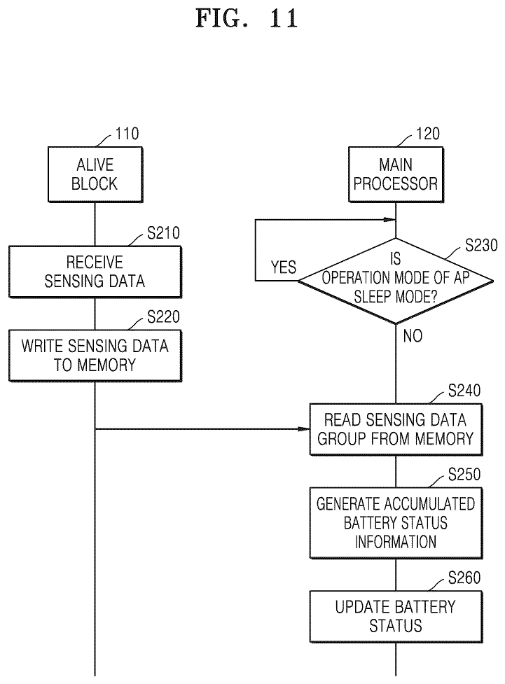

FIG. 11 is a flowchart for explaining an operating method of an electronic apparatus, according to some example embodiments. FIG. 11 may be a flowchart for explaining an operating method of the electronic apparatus 30a of FIG. 8 and the electronic apparatus 30b of FIG. 10. Hereinafter, the operation of the electronic apparatus 30a of FIG. 8 is mainly described, but it may be understood that the electronic apparatus 30b of FIG. 10 may operate in the same (or in a similar) manner. FIG. 11 may be explained with reference to FIGS. 1, 8, and 10, and redundant descriptions may be omitted.

Referring to FIG. 11, in operation S210, the electronic apparatus 30a may sense the battery 300 via the battery sensing circuit 200. The battery sensing circuit 200 may generate the sensing data SD based on a sensing result. The alive block 110 may receive the sensing data SD from the battery sensing circuit 200.

In operation S220, the electronic apparatus 30a may write the sensing data SD received from the battery sensing circuit 200 to the memory 111 via the auxiliary processor 112 of the alive block 110.

In some example embodiments, regardless of whether the operation mode of the application processor 100b is the active mode or the sleep mode, the alive block 110 may store the sensing data SD in the memory 111.

In some example embodiments, the alive block 110 may perform operation S210 and operation S220 periodically (for example, at each reference period).

In operation S230, when the operation mode of the application processor 100b is the sleep mode, the main processor 120 of the electronic apparatus 30a may stand by without performing subsequent operations. In other words, the main processor 120 may stand by without performing operations after operation S230 until the operation mode of the application processor 100b becomes the active mode.

In some example embodiments, when the operation mode of the application processor 100b is the sleep mode, the main processor 120 may be in an inactive state.

In some example embodiments, when the operation mode of the application processor 100b is the sleep mode, only operation S210 and operation S220 may be periodically repeated.

In operation S240, when the operation mode of the application processor 100b is the active mode as a result of determination in operation S230, the main processor 120 may read the sensing data group SDG from the memory 111.

In some example embodiments, the main processor 120 may read the sensing data group SDG from the memory 111 and initialize the memory 111 by erasing the sensing data group SDG stored in the memory 111.

In operation S250, the main processor 120 may generate the accumulated battery status information ABSI based on the read sensing data group SDG.

In operation S260, the electronic apparatus 30a may update a battery status (for example, the remaining capacity of battery and the degree of battery deterioration) of the electronic apparatus 30a based on the accumulated battery status information ABSI.

In some example embodiments, the electronic apparatus 30a may further include a display apparatus such as a display. The battery status may be displayed on the display apparatus, such as a display, included in the electronic apparatus 30a so as to be visually identifiable by a user.

In some example embodiments, the electronic apparatus 30a may perform operation S230 to operation S260 periodically (for example, at each reference period).

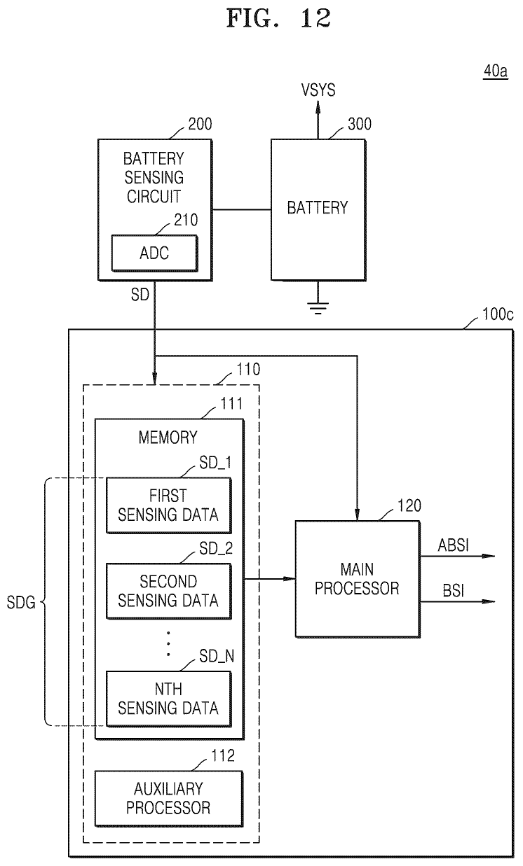

FIG. 12 is a diagram for explaining an electronic apparatus 40a, according to some example embodiments. FIG. 12 may be explained with reference to FIG. 1, and redundant descriptions may be omitted.

Referring to FIG. 12, the electronic apparatus 40a of FIG. 12 may correspond to the electronic apparatus 10 of FIG. 1. The electronic apparatus 40a may include an application processor 100c, the battery sensing circuit 200, and the battery 300. The battery 300 may provide power to operate (or power used or required to operate) the electronic apparatus 40a, via the operating voltage VSYS.

The application processor 100c may include the alive block 110 and the main processor 120. The alive block 110 may include the memory 111 and the auxiliary processor 112.

The memory 111 may store the sensing data group SDG. The sensing data group SDG may include the first to Nth sensing data SD_1 to SD_N (wherein n is a natural number of 2 or more). The first to N^{th} sensing data SD_1 to SD_N may be data provided from the battery sensing circuit 200.

In some example embodiments, when the application processor 100c is in the sleep mode, the electronic apparatus 40a may store the sensing data SD in the memory 111. In some example embodiments, when the application processor 100c is in the active mode, the electronic apparatus 40a may process the sensing data SD via the main processor 120.

In some example embodiments, when the application processor 100c is in the sleep mode, the battery sensing circuit 200 may provide the sensing data SD to the alive block 110. The alive block 110 may store the received sensing data SD in the memory 111.

In some example embodiments, when the application processor 100c is in the active mode, the battery sensing circuit 200 may provide the sensing data SD to the main processor 120.

As the auxiliary processor 112 writes, to the memory 111, the sensing data SD received from the battery sensing circuit 200, the sensing data SD may be stored in the memory 111.

In some example embodiments, the battery sensing circuit 200 may sense the battery 300 at each reference period (for example, every second), and the alive block 110 may receive the sensing data SD from the battery sensing circuit 200 at each reference period and may store the received sensing data SD.

In some example embodiments, when the operation mode of the application processor 100c is changed from the sleep mode to the active mode, the main processor 120 may read the sensing data group SDG stored in the memory 111.

In some example embodiments, the main processor 120 may read the sensing data group SDG from the memory 111 and initialize the memory 111 by erasing the sensing data group SDG stored in the memory 111.

In some example embodiments, the auxiliary processor 112 may not be deactivated (e.g., may be in an active state) even when the application processor 100c operates in the sleep mode. The main processor 120 may be deactivated when the application processor 100c operates in the sleep mode.

The main processor 120 may generate the accumulated battery status information ABSI, by performing a calculation based on the sensing data group SDG and the FG algorithm. The accumulated battery status information ABSI may be information that cumulatively includes battery status information at each time point, from the first time point to the N^{th} time point.

In some example embodiments, when the application processor 100c is in the active mode (for example, the operation mode remains in the active mode after being changed from the sleep mode to the active mode), the battery sensing circuit 200 may provide the sensing data SD to the main processor 120. The main processor 120 may generate the battery status information BSI, by performing a calculation using the FG algorithm based on the sensing data SD received from the battery sensing circuit 200. The battery status information BSI may be information representing the status of the battery 300 at a time point at which the battery sensing circuit 200 senses the battery 300. Accordingly, the electronic apparatus 40a may keep indicating the status of the battery 300.

In some example embodiments, the application processor 100c may communicate with the battery sensing circuit 200 via the I2C protocol. In some example embodiments, a signal line through which the sensing data SD is provided may branch into a signal line connected to the alive block 110 and a signal line connected to the main processor 120, within the application processor 100c.

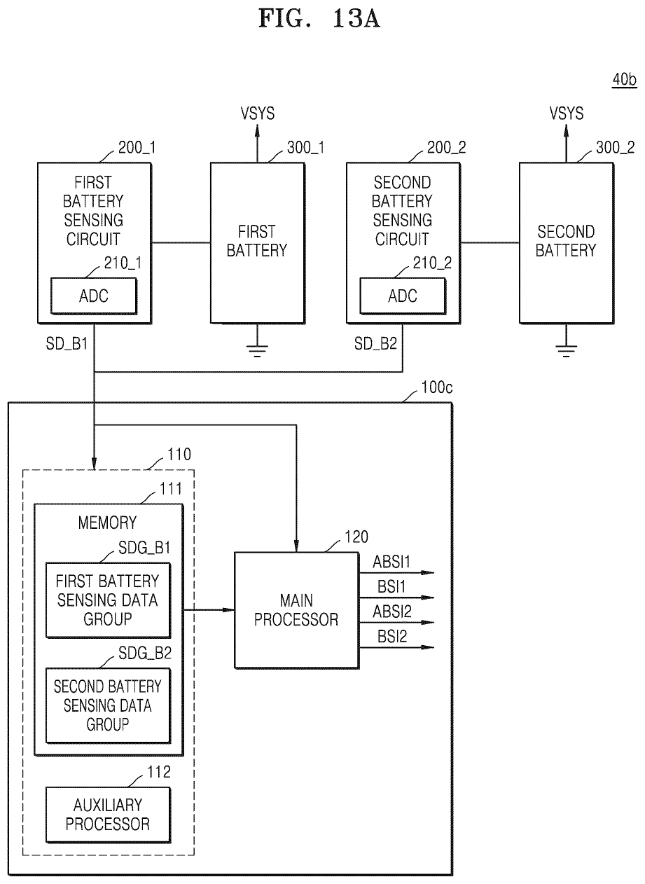

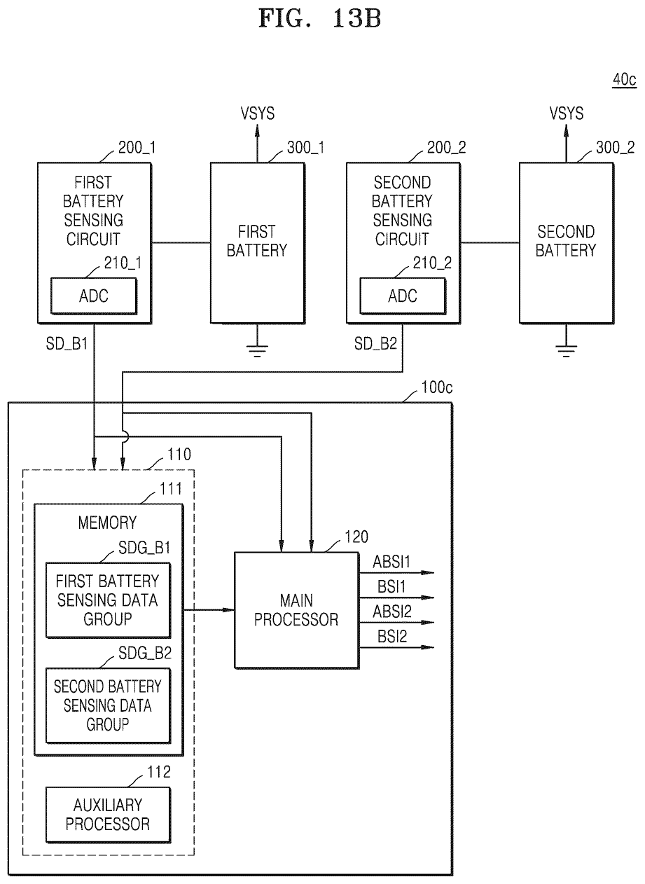

FIGS. 13A and 13B are diagrams for explaining an electronic apparatus 40b, according to some example embodiments. FIGS. 13A and 13B may be explained with reference to FIGS. 1 and 12, and redundant descriptions may be omitted.

Referring to FIG. 13A, the electronic apparatus 40b of FIG. 13A may correspond to the electronic apparatus 10 of FIG. 1. The electronic apparatus 40b of FIG. 13A may be configured similarly to the electronic apparatus 40a of FIG. 12, but unlike the electronic apparatus 40a of FIG. 12, the electronic apparatus 40b of FIG. 13A may include a plurality of batteries. FIG. 13A illustrates that the electronic apparatus 40b includes two batteries, e.g., the first battery 300_1 and the second battery 300_2, but example embodiments are not limited thereto.

The electronic apparatus 40b may include the application processor 100c, the first battery sensing circuit 200_1, the second battery sensing circuit 200_2, the first battery 300_1, and the second battery 300_2.

Each of the first battery 300_1 and the second battery 300_2 may provide power to operate (or provide power used or required to operate) the electronic apparatus 40b, via the operating voltage VSYS.

The first battery sensing circuit 200_1 may be electrically connected to the first battery 300_1. The first battery sensing circuit 200_1 may include the first ADC 210_1. The first battery sensing circuit 200_1 may provide the first battery sensing data SD_B1 corresponding to the first battery 300_1 to the alive block 110 or the main processor 120, by periodically sensing the first battery 300_1 via the first ADC 210_1.

The second battery sensing circuit 200_2 may be electrically connected to the second battery 300_2. The second battery sensing circuit 200_2 may include the second ADC 210_2. The second battery sensing circuit 200_2 may provide the second battery sensing data SD_B2 corresponding to the second battery 300_2 to the alive block 110 or the main processor 120, by periodically sensing the second battery 300_2 via the second ADC 210_2.

In some example embodiments, each of the first battery sensing data SD_B1 and the second battery sensing data SD_B2 may have the same structure as the sensing data SD shown in FIG. 3.

In some example embodiments, the first battery sensing data SD_B1 and the second battery sensing data SD_B2 may be provided to the application processor 100c via a same input/output pin provided in the application processor 100c. Communication between the application processor 100c and each of the first battery sensing circuit 200_1 and the second battery sensing circuit 200_2 may follow the I2C protocol. In some example embodiments, a signal line through which the first battery sensing data SD_B1 is provided and a signal line through which the second battery sensing data SD_B2 is provided may be connected as one signal line outside the application processor 100c. A signal line in the application processor 100c may branch into a signal line connected to the alive block 110 and a signal line connected to the main processor 120.

In some example embodiments, when the application processor 100c is in the sleep mode, the first battery sensing circuit 200_1 may provide the first battery sensing data SD_B1 to the alive block 110, and the second battery sensing circuit 200_2 may provide the second battery sensing data SD_B2 to the alive block 110. The alive block 110 may store the received first battery sensing data SD_B1 and the received second battery sensing data SD_B2 in the memory 111.

In some example embodiments, when the operation mode of the application processor 100c is changed from the sleep mode to the active mode, the main processor 120 may read, from the memory 111, the first battery sensing data group SDG_B1 and the second battery sensing data group SDG_B2, which are stored in the memory 111.

Each of the first battery sensing data group SDG_B1 and the second battery sensing data group SDG_B2 may correspond to the sensing data group SD_G shown in FIG. 9.

The main processor 120 may generate the first accumulated battery status information ABSI1 representing the status of the first battery 300_1 from the first time point to the N^{th} time point, by performing a calculation using the FG algorithm based on the read first battery sensing data group SDG_B1. The main processor 120 may generate the second accumulated battery status information ABSI2 representing the status of the second battery 300_2 from the first time point to the N^{th} time point, by performing a calculation using the FG algorithm based on the read second battery sensing data group SDG_B2.

In some example embodiments, when the application processor 100c is in the active mode, the first battery sensing circuit 200_1 may provide the first battery sensing data SD_B1 to the main processor 120, and the second battery sensing circuit 200_2 may provide the second battery sensing data SD_B2 to the main processor 120.

The main processor 120 may generate the first battery status information BSI1, by performing a calculation using the FG algorithm based on the first battery sensing data SD_B1 received from the first battery sensing circuit 200_1. In some example embodiments, the first battery status information BSI1 may be information representing the status of the first battery 300_1 at a time point at which the first battery sensing circuit 200_1 senses the first battery 300_1.

The main processor 120 may generate the second battery status information BSI2, by performing a calculation using the FG algorithm based on the second battery sensing data SD_B2 received from the second battery sensing circuit 200_2. In some example embodiments, the second battery status information BSI2 may be information representing the status of the second battery 300_2 at a time point at which the second battery sensing circuit 200_2 senses the second battery 300_2.

Referring to FIG. 13B, an electronic apparatus 40c of FIG. 13B may correspond to the electronic apparatus 40b of FIG. 13A. However, the application processor 100c of FIG. 13B may receive the first battery sensing data SD_B1 and the second battery sensing data SD_B2 via different input/output pins. Communication between the application processor 100c and each of the first battery sensing circuit 200_1 and the second battery sensing circuit 200_2 may follow the I2C protocol.

In some example embodiments, the first battery sensing data SD_B1 and the second battery sensing data SD_B2 may be provided to the application processor 100c via different input/output pins provided in the application processor 100c. For example, the first battery sensing data SD_B1 may be provided to the application processor 100c via a first input/output pin provided in the application processor 100c. The second battery sensing data SD_B2 may be provided to the application processor 100c via a second input/output pin provided in the application processor 100c.

A signal line through which the first battery sensing data SD_B1 is provided may branch into a signal line connected to the alive block 110 and a signal line connected to the main processor 120, within the application processor 100c.

A signal line through which the second battery sensing data SD_B2 is provided may branch into a signal line connected to the alive block 110 and a signal line connected to the main processor 120, within the application processor 100c.

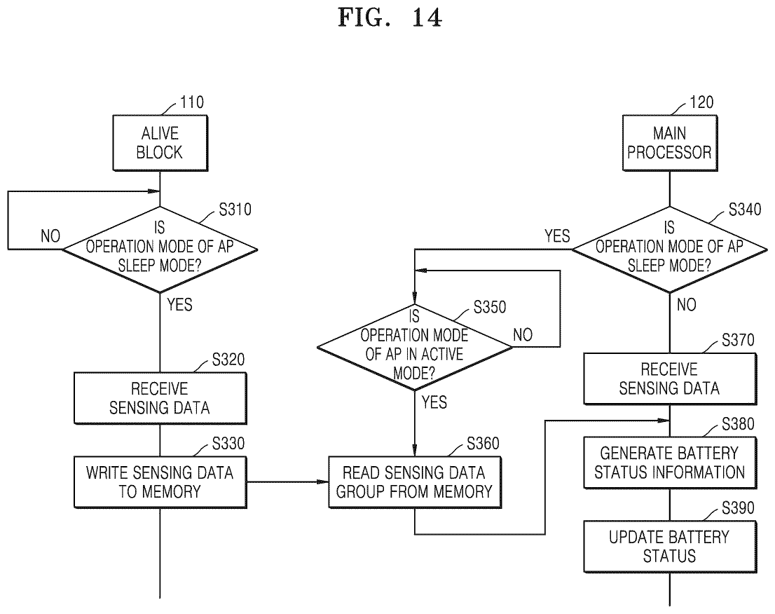

FIG. 14 is a flowchart for explaining an operating method of an electronic apparatus, according to some example embodiments. FIG. 14 may be a flowchart for explaining an operating method of the electronic apparatus 40a of FIG. 12, the electronic apparatus 40b of FIG. 13A, and the electronic apparatus 40c of FIG. 13B. Hereinafter, the operation of the electronic apparatus 40a of FIG. 12 is mainly described, but it may be understood that the electronic apparatus 40b of FIG. 13A and the electronic apparatus 40c of FIG. 13B may operate in the same (or in a similar) manner. FIG. 14 may be explained with reference to FIGS. 1, 12, and 13A-13B, and redundant descriptions may be omitted.

Referring to FIG. 14, in operation S310, the electronic apparatus 40a may determine, via the alive block 110, whether the operation mode of the application processor 100c is the sleep mode.

In operation S320, the electronic apparatus 40a may sense the battery 300 via the battery sensing circuit 200. The battery sensing circuit 200 may generate the sensing data SD based on a sensing result. As a result of the determination in operation S310, when it is determined that the operation mode of the application processor 100c is the sleep mode, the alive block 110 may receive the sensing data SD from the battery sensing circuit 200.

In some example embodiments, when the alive block 110 receives the sensing data SD from the battery sensing circuit 200, the main processor 120 may not receive the sensing data SD from the battery sensing circuit 200.

In operation S330, the electronic apparatus 40a may write the sensing data SD received from the battery sensing circuit 200 to the memory 111 via the auxiliary processor 112 of the alive block 110.

In some example embodiments, when the operation mode of the application processor 100c is the sleep mode, the alive block 110 may perform operation S320 and operation S330 periodically (for example, at each reference period).

In operation S340, when the operation mode of the application processor 100c is the sleep mode, the main processor 120 of the electronic apparatus 40a may stand by without performing subsequent operations.

In some example embodiments, when the operation mode of the application processor 100c is the sleep mode, the main processor 120 may be in an inactive state.

In some example embodiments, when the operation mode of the application processor 100c is the sleep mode, the electronic apparatus 40a may periodically repeat only operation S320 and operation S330.

In operation S350, when the operation mode of the application processor 100c is the sleep mode as a result of determination in operation S340, the main processor 120 of the electronic apparatus 40a may stand by without performing subsequent operations until the operation mode of the application processor 100c is changed to the active mode.

In operation S360, when the operation mode of the application processor 100c is changed from the sleep mode to the active mode as a result of determination in operation S350, the main processor 120 may read the sensing data group SDG from the memory 111.

In some example embodiments, when the main processor 120 performs operation S360, operation S370 may be omitted, and the main processor 120 may then perform operation S380 and operation S390.

In some example embodiments, the main processor 120 may read the sensing data group SDG from the memory 111 and initialize the memory 111 by erasing the sensing data group SDG stored in the memory 111.

In operation S370, when the operation mode of the application processor 100c is the active mode as a result of determination in operation S340, the main processor 120 may receive the sensing data SD from the battery sensing circuit 200.

In some example embodiments, when the main processor 120 receives the sensing data SD from the battery sensing circuit 200, the alive block 110 may not receive the sensing data SD from the battery sensing circuit 200.

In operation S380, the main processor 120 may generate the accumulated battery status information ABSI based on the sensing data group SDG read according to operation S360. Alternatively or additionally, the main processor 120 may generate the battery status information BSI based on the sensing data SD received from the battery sensing circuit 200 according to operation S370.

In operation S390, the electronic apparatus 40a may update a battery status (for example, the remaining capacity of battery and the degree of battery deterioration) of the electronic apparatus 40a based on the accumulated battery status information ABSI.

In some example embodiments, the electronic apparatus 40a may further include a display apparatus such as a display. The battery status may be displayed on the display apparatus, such as a display, included in the electronic apparatus 40a so as to be visually identifiable by a user.

In some example embodiments, the electronic apparatus 40a may perform operation S340 to operation S390 periodically (for example, at each reference period).

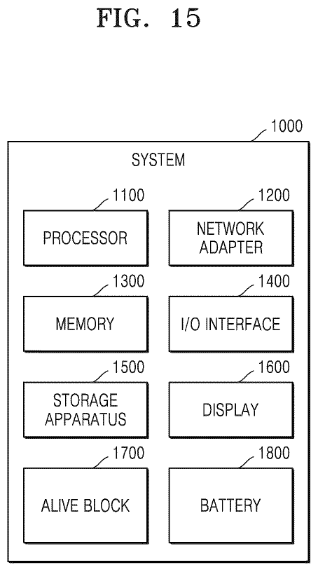

FIG. 15 is a block diagram illustrating a system 1000, according to some example embodiments.

Referring to FIG. 15, the system 1000 may correspond to the electronic apparatus 10 described with reference to the drawings. The system 1000 may refer to any system including a general-purpose or special-purpose computing system. For example, the system 1000 may include a PC, a server computer, a laptop computer, a home appliance, etc. As shown in FIG. 15, the system 1000 may include at least one processor 1100, a network adapter 1200, a memory 1300, an input/output interface 1400, a storage system 1500, a display 1600, an alive block 1700, and a battery 1800.

The at least one processor 1100 may execute a program module including a computer system executable instruction. The program module may include routines, programs, objects, components, logic, data structures, etc., which perform a certain task or implement a certain abstract data type. The memory 1300 may include a computer system readable medium in the form of volatile memory, such as RAM. The at least one processor 1100 may access the memory 1300 and may execute instructions loaded in the memory 1300. The storage system 1500 may be a non-volatile storage system and may store information in a non-volatile storage, and in some example embodiments, the storage system 1500 may include at least one program product including a program module configured to perform training of machine learning models for the layout simulation described above with reference to the drawings. A program may include, as non-limiting examples, an OS, at least one application, other program modules, and program data.

The network adapter 1200 may provide access to a local area network (LAN), a wide area network (WAN), and/or a public network (for example, Internet). The input/output interface 1400 may provide a communication channel with peripheral apparatuses such as a keyboard, a pointing apparatus, and an audio system. The display 1600 may output a variety of information for a user to check.

The alive block 1700 may be a hardware component that operates (or always operates) even when the system 1000 is operating in the sleep mode.

The battery 1800 may be configured to supply operating power to the system 1000. Although FIG. 15 illustrates only one battery (e.g., the battery 1800), example embodiments are not limited thereto. For example, the system 1000 may include two or more batteries.

In some example embodiments, the operating method of the electronic apparatus may be implemented in a computer program product. The computer program product may include a non-transitory computer-readable medium (or storage medium) including computer-readable program instructions for causing the at least one processor 1100 to generate status information for the battery 1800. The computer-readable instructions may be, as non-limiting examples, assembler instructions, instruction set architecture (ISA) instructions, machine instructions, machine-dependent instructions, microcode, firmware instructions, configuration data, or source code or object code written in at least one programming language.

The computer-readable medium may be any type of medium capable of non-transitorily retaining and storing instructions that are executed by the at least one processor 1100 or any instruction-executable apparatus. The computer-readable medium may be, but is not limited to, an electronic storage apparatus, a magnetic storage apparatus, an optical storage apparatus, an electromagnetic storage apparatus, a semiconductor storage apparatus, or any combination thereof. For example, the computer-readable medium may be a mechanically encoded apparatus, such as a portable computer diskette, a hard disk, RAM, ROM, electrically erasable programmable ROM (EEPROM), flash memory, SRAM, CD, DVD, a memory stick, a floppy disk, a punch card, or any combination thereof.

Some example embodiments of inventive concepts provide a method of operation of an electronic apparatus, the method including sensing a battery via a battery sensing circuit, receiving a sensing data from the battery sensing circuit, generating battery status information based on the sensing data, and updating a battery status based on the battery status information.

In some example embodiments, in the method of operation of an electronic apparatus, the sensing the battery includes generating the sensing data based on a sensing result.

In some example embodiments, in the method of operation of an electronic apparatus, the sensing result includes at least one of a current value of the battery, a voltage value of the battery, or a temperature value of the battery.

In some example embodiments, the method of operation of an electronic apparatus further includes storing the sensing data in a memory of the electronic apparatus, and the sensing data is received by the electronic apparatus via an alive block.

In some example embodiments, the method of operation of an electronic apparatus further includes reading the sensing data via an auxiliary processor, and the battery status information is generated based on the reading of the sensing data.

In some example embodiments, the method of operation of an electronic apparatus is performed periodically at a particular reference period.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FGPA), a System-on-Chip (SoC), a programmable logic unit, a microprocessor, application-specific integrated circuit (ASIC), etc.

Some example embodiments of inventive concepts provide an electronic apparatus comprising a first battery and a second battery configured to supply power to the electronic apparatus, a first battery sensing circuit configured to generate first battery sensing data based on sensing the first battery, the first battery sensing data corresponding to the first battery, a second battery sensing circuit configured to generate second battery sensing data based on sensing the second battery, the second battery sensing data corresponding to the second battery and an application processor including an alive block, wherein the alive block includes a memory configured to store the first battery sensing data and the second battery sensing data and an auxiliary processor configured to generate first battery status information based on the first battery sensing data and generate second battery status information based on the second battery sensing data, and the alive block is configured to generate the first battery status information and the second battery status information in response to the application processor operating in a sleep mode.

Some example embodiments of inventive concepts provide an electronic apparatus comprising a first battery and a second battery configured to supply power to the electronic apparatus, a first battery sensing circuit configured to generate first battery sensing data based on sensing the first battery, the first battery sensing data corresponding to the first battery, a second battery sensing circuit configured to generate second battery sensing data based on sensing the second battery, the second battery sensing data corresponding to the second battery, and an application processor including an alive block and a main processor, wherein the alive block includes a memory configured to store the first battery sensing data and the second battery sensing data, and an auxiliary processor configured to write the first battery sensing data and the second battery sensing data to the memory, and the main processor is configured to read the first battery sensing data and the second battery sensing data from the memory, generate first battery status information based on the first battery sensing data, and generate second battery status information based on the second battery sensing data.

Some example embodiments of inventive concepts provide an electronic apparatus comprising a first battery and a second battery configured to supply power to the electronic apparatus, a first battery sensing circuit configured to generate first battery sensing data based on sensing the first battery, the first battery sensing data corresponding to the first battery, a second battery sensing circuit configured to generate second battery sensing data based on sensing the second battery, the second battery sensing data corresponding to the second battery and an application processor including an alive block and a main processor, wherein the alive block includes a memory configured to store the first battery sensing data and the second battery sensing data and an auxiliary processor configured to write the first battery sensing data and the second battery sensing data to the memory in response to the application processor operating in a sleep mode, and the main processor is configured to read the first battery sensing data and the second battery sensing data from the memory, generate first accumulated battery status information based on the first battery sensing data, and generate second accumulated battery status information based on the second battery sensing data, in response to an operation mode of the application processor being changed from the sleep mode to an active mode.

While inventive concepts have been particularly shown and described with reference to some example embodiments thereof, it will be understood that various changes in form and details may be made therein without departing from the spirit and scope of the following claims.

What is claimed is:

1. An electronic apparatus comprising:
a battery configured to supply power to the electronic apparatus;
a battery sensing circuit electrically connected to the battery and configured to generate sensing data corresponding to the battery; and
an application processor including an alive block,
wherein the alive block includes
a memory configured to store the sensing data; and
an auxiliary processor configured to generate battery status information based on the sensing data, and
the alive block is configured to generate the battery status information in response to the application processor operating in a sleep mode.

2. The electronic apparatus of claim 1, wherein
the application processor further comprises a main processor configured to be activated in response to the application processor operating in an active mode,
a power consumption of the auxiliary processor is less than a power consumption of the main processor, and
the alive block is configured to generate the battery status information based on the sensing data in response to the application processor operating in the active mode.

3. The electronic apparatus of claim 1, wherein the sensing data comprises:
a current value representing a current of the battery at a sensing time point at which the battery sensing circuit senses the battery;
a voltage value representing a voltage of the battery at the sensing time point; and
a temperature value representing a temperature of the battery at the sensing time point.

4. The electronic apparatus of claim 1, wherein
the battery sensing circuit is configured to sense the battery at each reference period, and
the alive block is configured to receive the sensing data from the battery sensing circuit at each reference period.

5. The electronic apparatus of claim 1, wherein the battery comprises:
a current sensing resistor;
a battery cell electrically connected to the current sensing resistor; and
a voltage divider circuit including a thermistor and a reference resistor.

6. The electronic apparatus of claim 5, wherein the battery sensing circuit comprises an analog-to-digital converter (ADC) configured to
generate a first digital value based on voltages at both terminals of the current sensing resistor, the first digital value corresponding to a current of the battery,
generate a second digital value based on voltages at both terminals of the battery cell, the second digital value corresponding to a voltage of the battery, and
generate a third digital value based on voltages at both terminals of the thermistor, the third digital value corresponding to a temperature of the battery.

7. The electronic apparatus of claim 1, wherein the battery status information comprises at least one of:
state of charge information representing an amount of energy remaining in the battery;
state of battery health information representing a degree of deterioration of the battery; or
internal short-circuit information representing whether there is a short circuit inside the battery.

8. An electronic apparatus comprising:
a battery configured to supply power to the electronic apparatus;
a battery sensing circuit electrically connected to the battery and configured to generate sensing data corresponding to the battery; and
an application processor including an alive block and a main processor,
wherein the alive block includes
a memory configured to store the sensing data; and
an auxiliary processor configured to write the sensing data to the memory, and
the main processor is configured to read the sensing data from the memory and generate battery status information based on the sensing data.

9. The electronic apparatus of claim 8, wherein the main processor is configured to read the sensing data from the memory and generate the battery status information based on the sensing data, in response to the application processor operating in an active mode.

10. The electronic apparatus of claim 9, wherein the main processor is configured to initialize the memory after reading the sensing data from the memory.

11. The electronic apparatus of claim 8, wherein the sensing data comprises:
a current value representing a current of the battery at a sensing time point at which the battery sensing circuit senses the battery;
a voltage value representing a voltage of the battery at the sensing time point; and
a temperature value representing a temperature of the battery at the sensing time point.

12. The electronic apparatus of claim 8, wherein
the battery sensing circuit is configured to sense the battery at each reference period, and
the alive block is configured to receive the sensing data from the battery sensing circuit at each reference period.

13. The electronic apparatus of claim 8, wherein the battery status information comprises at least one of:
state of charge information representing an amount of energy remaining in the battery;
state of battery health information representing a degree of deterioration of the battery; or
internal short-circuit information representing whether there is a short circuit inside the battery.

14. An electronic apparatus comprising:
a battery configured to supply power to the electronic apparatus;
a battery sensing circuit electrically connected to the battery and configured to generate sensing data corresponding to the battery; and
an application processor including an alive block and a main processor,
wherein the alive block includes
a memory configured to store a sensing data group including the sensing data; and
an auxiliary processor configured to write the sensing data to the memory in response to the application processor operating in a sleep mode, and
the main processor is configured to read the sensing data group from the memory and generate accumulated battery status information based on the sensing data group, in response to an operation mode of the application processor being changed from the sleep mode to an active mode.

15. The electronic apparatus of claim 14, wherein the main processor is configured to receive the sensing data from the battery sensing circuit and generate battery status information based on the sensing data, in response to the application processor operating in the active mode.

16. The electronic apparatus of claim 14, wherein the main processor is configured to read the sensing data from the memory and initialize the memory.

17. The electronic apparatus of claim 14, wherein the application processor is configured to operate in the sleep mode at a first time point and a second time point, and
the sensing data group comprises:
first sensing data generated by the battery sensing circuit at the first time point; and
second sensing data generated by the battery sensing circuit at the second time point.

18. The electronic apparatus of claim 14, wherein
the battery sensing circuit is configured to sense the battery at each reference period,
the alive block is configured to receive the sensing data at each reference period from the battery sensing circuit, in response to the application processor operating in the sleep mode, and
the main processor is configured to receive the sensing data at each reference period from the battery sensing circuit, in response to the application processor operating in the active mode.

19. The electronic apparatus of claim 14, wherein the battery comprises:
a current sensing resistor;
a battery cell electrically connected to the current sensing resistor; and
a voltage divider circuit including a thermistor and a reference resistor.

20. The electronic apparatus of claim 19, wherein the battery sensing circuit comprises an analog-to-digital converter (ADC) configured to
generate a first digital value based on voltages at both terminals of the current sensing resistor, the first digital value corresponding to a current of the battery,
generate a second digital value based on voltages at both terminals of the battery cell, the second digital value corresponding to a voltage of the battery, and
generate a third digital value based on voltages at both terminals of the thermistor, the third digital value corresponding to a temperature of the battery.
